(19) United States
(12) Patent Application Publication
(10) Pub. No.: US 2023/0420384 A1
(43) Pub. Date: Dec. 28, 2023

(54) SLOTTED STIFFENER FOR A PACKAGE SUBSTRATE

(71) Applicant: Intel Corporation, Santa Clara, CA (US)

(72) Inventors: Kavitha NAGARAJAN, Bangalore (IN); Eng Huat GOH, Ayer Itam (MY); Min Suet LIM, Gelugor (MY); Telesphor KAMGAING, Chandler, AZ (US); Chee Kheong YOON, Bayan Lepas (MY); Jooi Wah WONG, Bukit Mertajam (MY); Chu Aun LIM, Hillsboro, OR (US)

(21) Appl. No.: 17/848,639

(22) Filed: Jun. 24, 2022

(51) Int. Cl. H01L 23/552; H01L 23/367; H01L 23/16; H01L 23/00

(52) U.S. Cl. CPC H01L 23/552; H01L 23/367; H01L 23/16; H01L 23/562

(57) ABSTRACT

Embodiments herein relate to systems, apparatuses, or processes directed to a stiffener for a surface of a semiconductor package, where the stiffener includes slots that allow a gasket to go over the stiffener to electrically couple with a ground or a VSS of the semiconductor package. In embodiments, the gasket may include a material that blocks or absorbs EMI or RFI. Other embodiments may be described and/or claimed.

### FIELD

Embodiments of the present disclosure generally relate to the field of package assemblies, and in particular package assemblies that generate electromagnetic interference (EMI) or radio frequency interference (RFI).

### BACKGROUND

Continued reduction in end product size of mobile electronic devices such as smart phones and ultrabooks is a driving force for the development of reduced size system in package components. In particular, reduced size system components that may generate or be susceptible to EMI or RFI.

### BRIEF DESCRIPTION OF THE DRAWINGS

FIG. 1 illustrates a cross section side view and a top-down view of a legacy implementation of a stiffener on a package with microstripline routing near a surface of a substrate of the package.

FIGS. 2A-2B illustrate a cross section side view and a top-down view of a package that includes a stiffener with slots, and a cross section side view and a top-down view of an EMI gasket to be inserted into the stiffener, in accordance with various embodiments.

FIG. 3 illustrates a cross section side view of a package that includes multiple dies and a stiffener with slots coupled with an EMI gasket and a heat spreader, in accordance with various embodiments.

FIGS. 4A-4E illustrate stages in a manufacturing process for creating a package that includes a stiffener with slots coupled with an EMI gasket and the heat spreader, in accordance with various embodiments.

FIGS. 5A-5B illustrate a partial list of configurations of stiffeners with slots and EMI gaskets, in accordance with various embodiments.

FIG. 6 illustrates an example of a process for creating a package that includes a stiffener with slots, in accordance with various embodiments.

FIG. 7 schematically illustrates a computing device, in accordance with embodiments.

### DETAILED DESCRIPTION

Embodiments of the present disclosure may generally relate to systems, apparatus, and/or processes directed to a stiffener for a surface of a semiconductor package, where the stiffener includes slots that allow a gasket to go over the stiffener to electrically couple with a ground or a VSS of the semiconductor package. In embodiments, the gasket may include a material that blocks or absorbs EMI or RFI. In embodiments, an electrically conductive epoxy, or resin, may be inserted into the slots to electrically couple a ground at the surface of the semiconductor package with the gasket and to physically couple the gasket with the stiffener.

In embodiments, the stiffener may surround electrical components on the surface of a substrate of the semiconductor package. These components may include, for example, a die or traces, which may be located at or proximate to a surface of the substrate, and may be underneath the gasket and within a perimeter of the stiffener. In embodiments, the traces may carry high-speed signals during package operation, or may be microstripline routings used for high-speed signals.

During operation, these traces, the die, and/or other components within the package may generate EMI or RFI that may be detrimental to components near the semiconductor package. In embodiments, the grounded gasket may serve to block or absorb any EMI or RFI generated during operation of the semiconductor package. This will be increasingly true as the speed of memory and other high-speed input/output (HSIO) interfaces in future semiconductor packages continue to increase.

Embodiments may facilitate reducing layers within a substrate, which may also be referred to as reducing substrate capacity. In particular, the layer count of a substrate may be reduced by moving microstripline routing to a surface of the substrate of the package, thus reducing the overall package Z-height. In legacy implementations, such high-speed routing may occur within the substrate to minimize EMI or RFI generated by the routing and may require additional grounding layers for shielding which increases overall legacy substrate thickness.

In legacy implementations, sputtering or conformal coating may be used to apply EMI or RFI absorbing materials on the surface of the substrate; however this is not a cost-effective solution it may not be widely available.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

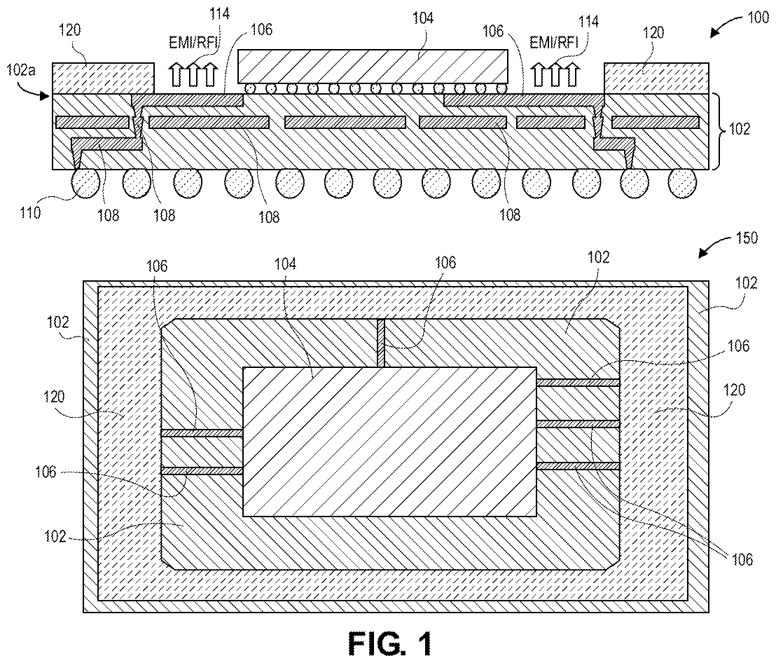

FIG. 1 illustrates a cross section side view and a top-down view of a legacy implementation of a stiffener on a package with microstrip line routing near a surface of a substrate of the package. Legacy package 100 shows a cross section side view that includes a substrate 102 that includes a plurality of layers, a die 104 that is coupled with the substrate 102, and microstrip line routings 106 that are at or near a surface 102a of the substrate 102.

A microstrip line, such as microstrip line 106, may include a planar transmission line that includes copper or some other conductive metal that may be used for high speed interface interconnections. The microstrip line 106 may be routed in the package substrate 102 surface layer on a dielectric, and has air above the microstrip line 106. The substrate 102 may also include additional routings 108, including power planes, traces, and vias that may electrically couple with one or more solder balls 110 of a ball grid array (BGA) 110.

The microstrip line 106 differs from a stripline (not shown) which will be in between two conductive layers (not shown). As a result, legacy substrates that implement a stripline require additional layers within the substrate to support a ground plane and power plane associated with a stripline conductor.

A legacy stiffener 120 may be placed on the surface 102a of the substrate 102. In embodiments, the legacy stiffener 120 may be a metal or may be some other compound that may have a greater rigidity than the substrate 102, and therefore provide additional support against flexing or warping of the substrate 102 during installation or operation.

During operation of the package, high-speed signals that are routed along the microstrip lines 106 may generate EMI/RFI 114. The amount and nature of the EMI/RFI 114 is based on the frequency of the signal along the microstrip lines 106. As a result, EMI/RFI 114 will be emitted from the legacy package 100 and out into the area surrounding the package. This has the possibility of damaging or disrupting the operation of nearby devices or components (not shown). In particular, the EMI/RFI 114 may affect the operation of any antennas (not shown) that may be proximate to the legacy package 100, or on the legacy package 100.

Legacy package 150 shows a top-down view of substrate 102, with the legacy stiffener 120 on the substrate 102, at microstrip lines 106 running from the die 104 along the surface of the substrate 102. Note that in embodiments, there may be a thin film (not shown) above the microstrip lines 106, which may electrically isolate the microstrip lines 106 from the legacy stiffener 120.

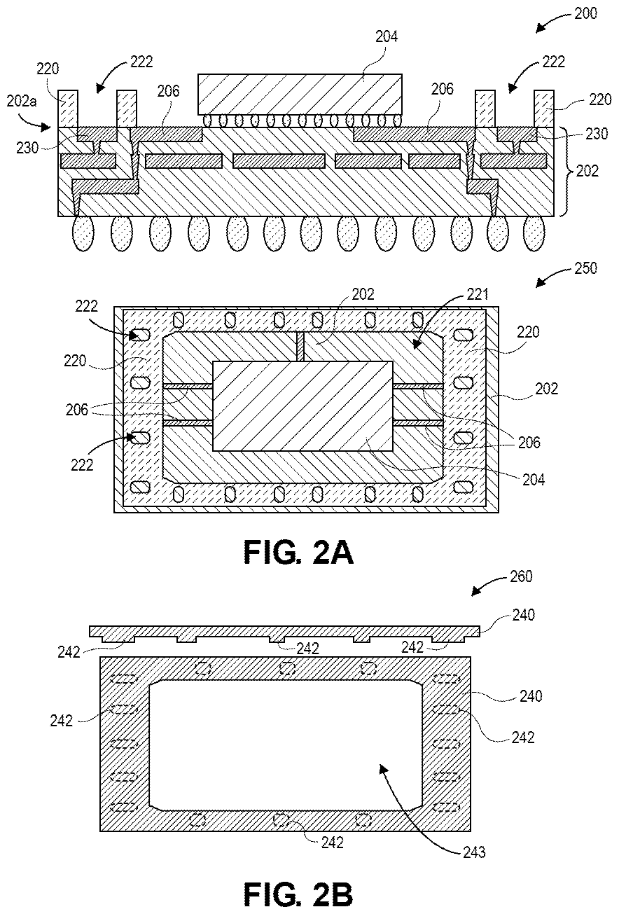

FIGS. 2A-2B illustrate a cross section side view and a top-down view of a package that includes a stiffener with slots, and a cross section side view and a top-down view of an EMI gasket to be inserted into the stiffener, in accordance with various embodiments. FIG. 2A shows package 200 that includes a substrate 202, a die 204 coupled with the substrate 202, and microstrip lines 206 at a surface 202a of the substrate 202. These may be similar to substrate 102, die 104, and microstrip lines 106 of FIG. 1.

In embodiments, a stiffener 220, which may be similar to legacy stiffener 120 of FIG. 1, is coupled with the surface 202a of the substrate 202. In embodiments, the stiffener 220 includes a plurality of slots 222 that extend through the stiffener 220 from one side to the other. In embodiments, at least some of the slots 222 may correspond with and may be positioned over a ground 230, which may be referred to as a VSS, on the surface 202a of the substrate 202. In embodiments, the stiffener 220 may be attached to the substrate 202 using a conductive epoxy or using some other similar attachment technique.

Package 250 shows a top-down view of the substrate 202 and of the stiffener 220 on the substrate 202. As shown, the stiffener 220 has a large opening 221 in the middle that surrounds the die 204 and surrounds at least a portion of the microstrip lines 206.

In embodiments, slots 222 may be spaced evenly apart. As shown, slots 222 may be on the stiffener 220 and may be roughly at equal distances from each other. In embodiments (not shown), the slots 222 may vary in their orientation and be unevenly distributed on the stiffener 220.

As shown, the slots 222 have a general elliptical shape, however in other embodiments this may not be the case. The shape of the slots 222 may include, but are not limited to, a circular shape, or a rectangular shape.

FIG. 2B shows a cross section side view and a top-down view of an EMI gasket 240 that may be inserted into the stiffener 220 of FIG. 2A. Diagram 260 shows a cross section side view of an EMI gasket 240 that includes a plurality of protrusions 242 that extend from a side of the EMI gasket 240. In embodiments, a depth of the protrusions 242 may be less than or equal to a depth of the slots 222 of FIG. 2A. In embodiments, a configuration of the protrusions 242 are selected to match a configuration of the slots 222 so that the protrusions 242 may be inserted into the slots 222 as the gasket 240 is placed on top of the stiffener 220.

In embodiments, material used in the EMI gasket 240 either block or absorb EMI or RFI. Examples of materials used in the EMI gasket 240 may include, but are not limited to beryllium copper, stainless steel, aluminum, mesh composites, copper alloy, silicone, or a nickel. In embodiments, a large opening 243, which may be similar in dimension to a large opening 221 of the stiffener 220 of FIG. 2A.

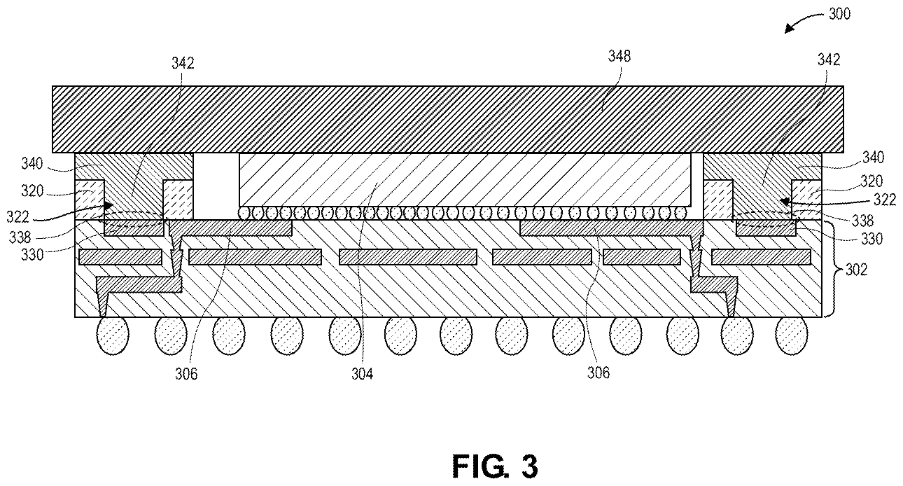

FIG. 3 illustrates a cross section side view of a package that includes multiple dies and a stiffener with slots coupled with an EMI gasket and a heat spreader, in accordance with various embodiments. Package 300 includes substrate 302, microstrip lines 306, ground 330, die 304, and stiffener 320, which may be similar to substrate 202, microstrip lines 206, ground 230, die 204, and stiffener 220 of FIG. 2A.

An EMI gasket 340, which may be similar to EMI gasket 240 of FIG. 2B, is fitted onto the stiffener 320, with the EMI gasket protrusions 342 inserted into the stiffener slot 322, which may be similar to stiffener slot 222 of FIG. 2A. In embodiments, an epoxy 338 may be placed within the stiffener slots 322 to secure the EMI gasket 340 onto the stiffener 320. In embodiments, the epoxy 338 may be an electrically conductive epoxy that will electrically couple the ground 330 with the EMI gasket 340.

In embodiments, a heat spreader 348 may be coupled to a top of the EMI gasket 340 using epoxy 338. In embodiments, the die 304 may be thermally coupled with the heat spreader 348, through either a direct thermal coupling or through one or more thermal interface materials (TIMs) (not shown).

In embodiments, the combination of the ground 330, electrically conductive epoxy 338, EMI gasket 340, and heat spreader 348 may form an EMI/RFI shield, which may be similar to a Faraday cage that will prevent or limit EMI/RFI emanating from the microstrip lines 306 during operation of the package 300.

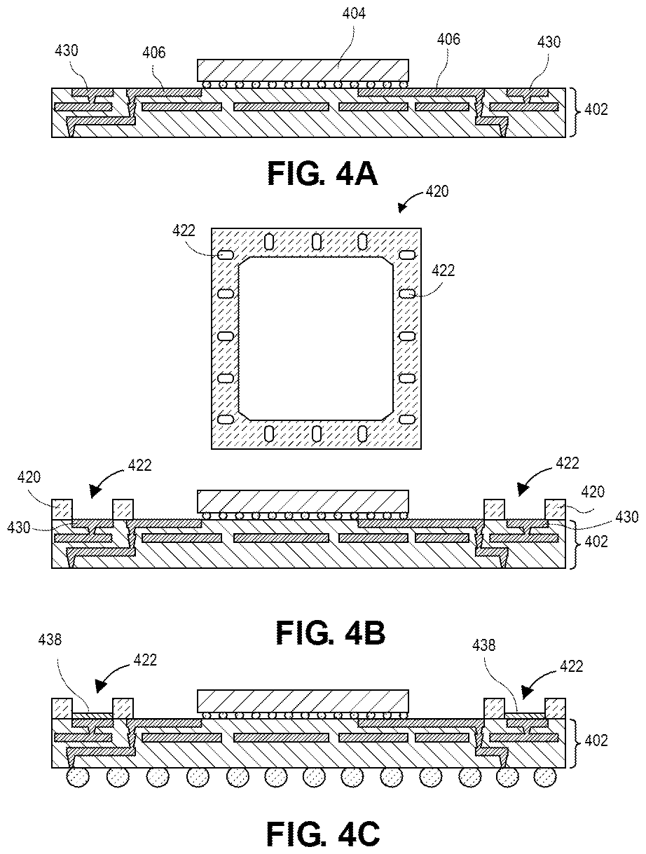

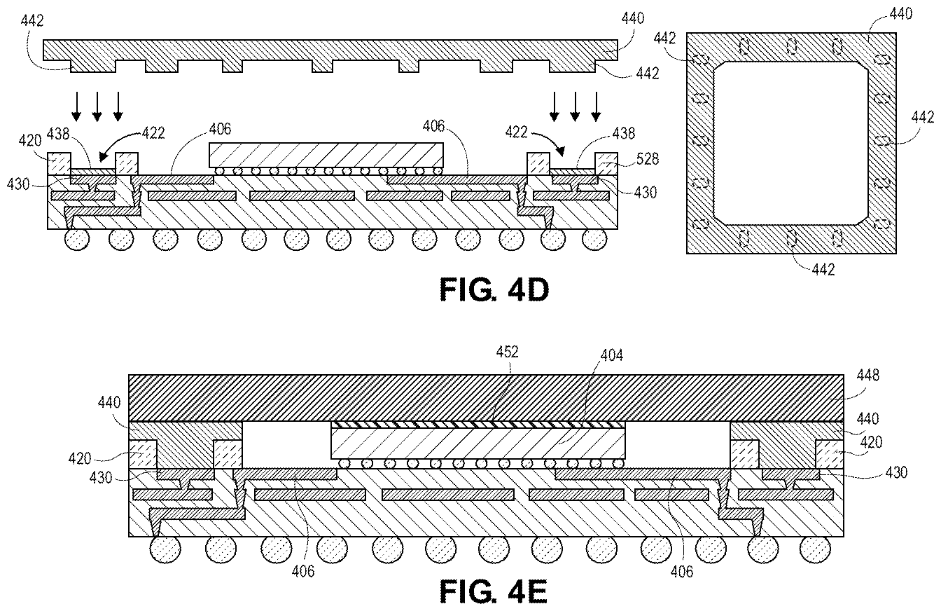

FIGS. 4A-4E illustrate stages in a manufacturing process for creating a package that includes a stiffener with slots coupled with an EMI gasket and the heat spreader, in accordance with various embodiments. The manufacturing stages in FIGS. 4A-4E may be performed using the techniques, apparatus, systems, and/or processes herein, and in particular with respect to FIGS. 1-3.

FIG. 4A illustrates a cross section side view of a stage in the manufacturing process where a partial package is provided, that includes a substrate 402, a die 404, microstrip lines 406, and grounds 430. In embodiments, the grounds 430 may be referred to as ground planes, and may be equivalent to a VSS electrical contact. These may be similar to substrate 202, die 204, microstrip lines 206, and grounds 230 of FIG. 2A. In embodiments, the substrate 402 may have multiple layers and include various metal routings within the substrate to connect the first side of the substrate to a second side of the substrate. In embodiments, the microstrip lines 406 may electrically couple with the die 404 at a surface of, or proximate to a surface of the substrate 402.

FIG. 4B illustrates a cross section side view of a stage in the manufacturing process where a stiffener 420, which may be similar to stiffener 220 of FIG. 2A, is placed on the substrate 402. In embodiments, at least some of the slots 422 of the stiffener 420 may be placed over the grounds 430 on the substrate 402. In embodiments, the stiffener 420 may be referred to as a slotted stiffener. In embodiments, the stiffener 420 may be of the varying thickness or an arbitrary shape based upon the position of the die 404 on the substrate 402. The stiffener 420 may be used to maintain planarity of the substrate 402. In embodiments, the stiffener 420 may include metal such as stainless steel. In embodiments, the slots 422 may be drilled or otherwise removed from the material used to create the stiffener 420.

In embodiments, the stiffener 420 may be a solid material, for example solid stainless steel, some other solid metal that may include an alloy, or some other solid material that may be used to maintain planarity of the substrate 402. In embodiments, the stiffener 420 may include multiple layers of material, such as a thin metal layer onto which a figure or other metal layer may be plated or built up. In these embodiments, the two metal layers may be of different metals or alloys, that may be chosen based on stiffness characteristics within various temperature ranges or within other conditions under which the substrate 402 may be operating. In other embodiments, the stiffener 420 may include a compound that includes carbon fiber or other similar materials. In embodiments, the stiffener 420 may be electrically conductive or partially electrically conductive.

In embodiments the stiffener 420 may be secured to the substrate 402 using an adhesive. In embodiments, one or more slots of the stiffener 420 may be aligned with one or more grounds 430, so that the one or more grounds 430 are accessible through the one or more slots 422.

FIG. 4C illustrates a cross section side view of a stage in the manufacturing process where an epoxy 438 is placed within the slots 422. In embodiments, the epoxy 438 may be electrically conductive, and electrically coupled with the grounds 430 on the substrate 402. In embodiments, by placing the epoxy 438 within the slots 422, the slots 422 may act as a dam to control the flow of the epoxy 438, so that the epoxy 438 does not flow onto a surface of the substrate 402 outside of the slots 422.

In embodiments, the epoxy 438 may be injected into the slots 422, or may be flowed into the slots 422 using a distribution mechanism (not shown). The amount of epoxy 438 placed into each of the slots 422 may vary depending upon a geometry of a gasket 440 described with respect to FIG. 4D.

FIG. 4D illustrates a cross section side view of a stage in the manufacturing process where a gasket 440, which may be similar to gasket 240 of FIG. 2B, is inserted into the stiffener 420. The gasket 440 is also shown in a top-down view. In embodiments, protrusions 442 on the bottom side of the gasket 440, which may be similar to protrusions 242 of FIG. 2B, are inserted within the slots 422 of the stiffener 420. In embodiments, the protrusions 442 will contact the epoxy 438, and will form a seal to secure the gasket 440 with the stiffener 420.

In embodiments, the epoxy 438 is an electrically conductive epoxy, and will electrically couple the gasket 440 with the ground 430. In embodiments, the gasket 440 includes an EMI/RFI blocking and/or absorption material to prevent EMI/RFI generated by the microstrip lines 406 during operation.

FIG. 4E illustrates a cross section side view of a stage in the manufacturing process where a heat spreader 448 is placed on top of the gasket 440. The heat spreader 448 may be similar to heat spreader 348 of FIG. 3. In embodiments, the heat spreader 448 may be physically and/or electrically coupled with the gasket 440 using an epoxy, or using some other adhesive material or technique. In embodiments, the ground 430, the gasket 440, and the heat spreader 448 may be electrically coupled and may form a Faraday cage to minimize or prevent EMI/RFI generated by the microstrip lines 406 during operation from escaping and affecting nearby devices (not shown) during operation.

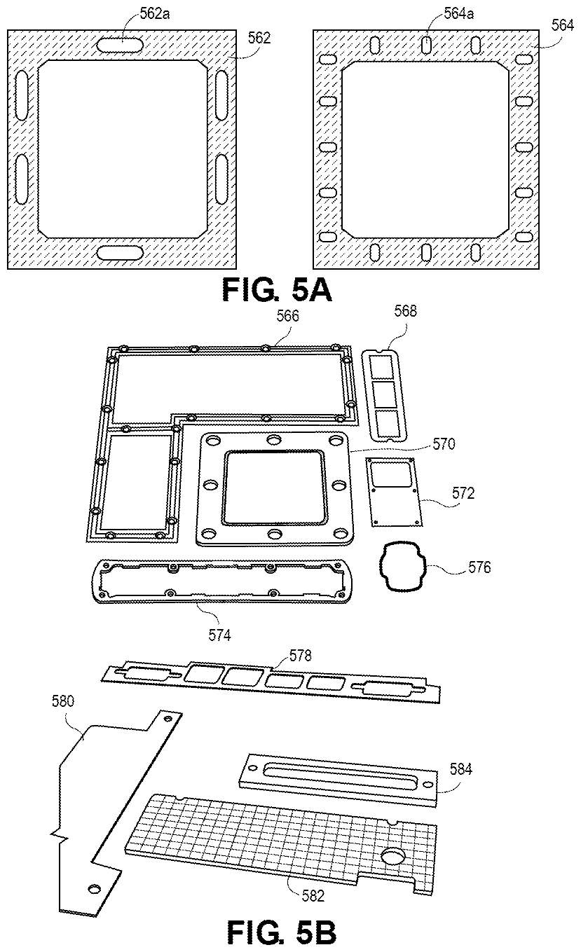

FIGS. 5A-5B illustrate a partial list of configurations of stiffeners with slots and EMI gaskets, in accordance with various embodiments. FIG. 5A shows example configurations of stiffeners with slots. In embodiments, stiffeners 562, 564 may have a general rectangular shape, however they may have slots 562a, 564a, respectively, with different geometries and in different locations depending upon the configuration of a gasket (not shown) to be used with the stiffeners 562, 564. In embodiments, stiffeners 562, 564 may be similar to stiffener 220 of FIG. 2A, stiffener 320 of FIG. 3, stiffener 420 of FIG. 4B. In embodiments, the overall shape and configuration of the stiffeners 562, 564 may be determined based on the layout, circuitry, and devices that are on a substrate, such as substrate 202 of FIG. 2A, substrate 302 FIG. 3, and substrate 402 of FIG. 4A, to which the stiffeners 562, 564 may be applied.

FIG. 5B shows example configurations of EMI gaskets. EMI gaskets 566, 568, 570, 572, 574, 576, 578, 580, 582, 584 show various configurations, geometries, and thickness. In embodiments, these EMI gaskets may be applied to the stiffeners that may be similar to stiffener 220 of FIG. 2A, stiffener 320 of FIG. 3, stiffener 420 of FIG. 4B, or stiffeners 562, 564 of FIG. 1n embodiments, the EMI gaskets may be similar to EMI gasket 240 of FIG. 2B, EMI gasket 340 of FIG. 3, or EMI gasket 440 of FIGS. 4D-4E.

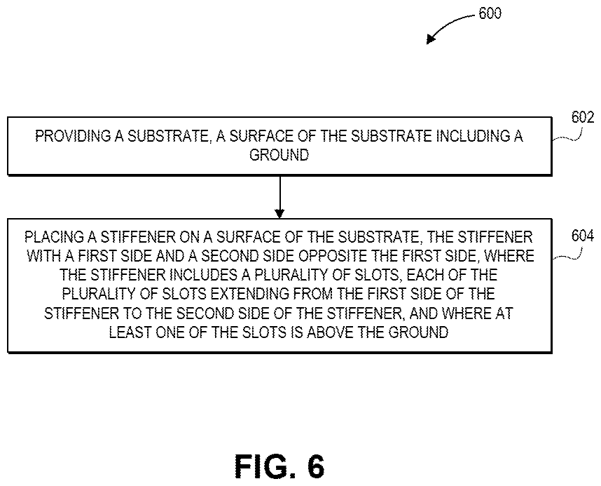

FIG. 6 illustrates an example of a process for creating a package that includes a stiffener with slots, in accordance with various embodiments. Process 600 may be implemented using the systems, apparatus, techniques, or processes described herein, and particularly with respect to FIGS. 1-5B.

At block 602, the process may include providing a substrate, a surface of the substrate including a ground. In embodiments, the substrate may be similar to substrate 202 of FIG. 2A, 302 FIGS. 3, and 402 of FIG. 4A. In embodiments, the ground may be similar to ground 230 of FIG. 2A, ground 330 of FIG. 3, or ground 430 of FIG. 4A.

At block 604, the process may further include placing a stiffener on a surface of the substrate, the stiffener with a first side and a second side opposite the first side, where the stiffener includes a plurality of slots, each of the plurality of slots extending from the first side of the stiffener to the second side of the stiffener, and where at least one of the slots is above the ground.

In embodiments, the stiffener may be similar to stiffener 220 of FIG. 2A, 320 of FIG. 3, or 420 of FIG. 4. In embodiments, the plurality of slots may be similar to slots 222 of FIG. 2A, 322 of FIG. 3, or 422 of FIG. 4. In embodiments, an epoxy, such as epoxy 438 of FIG. 4C may be placed within the plurality of slots, in order that a gasket, such as gasket 440 of FIG. 4B that includes protrusions 422 may be secured into the stiffener.

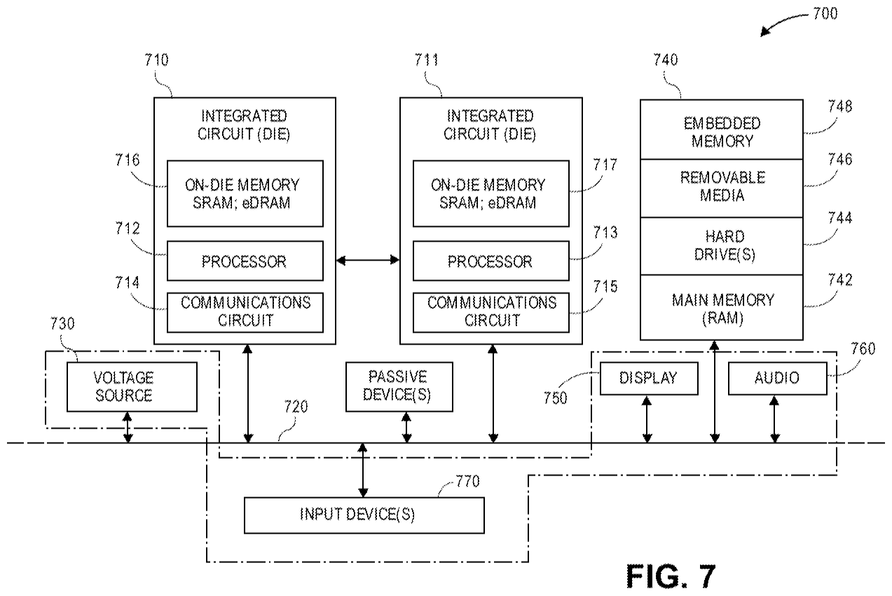

FIG. 7 is a schematic of a computer system 700, in accordance with an embodiment of the present invention. The computer system 700 (also referred to as the electronic system 700) as depicted can embody a slotted stiffener for a package substrate, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, a slotted stiffener for a package substrate, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having a slotted stiffener for a package substrate, according to any of the several disclosed embodiments and their equivalents, an electronic system, a computer system, one or more methods of fabricating an integrated circuit, and one or more methods of fabricating an electronic assembly that includes a package substrate having a slotted stiffener for a package substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a slotted stiffener for a package substrate embodiments and their equivalents. A foundation substrate may be included, as represented by the dashed line of FIG. 7. Passive devices may also be included, as is also depicted in FIG. 7.

### EXAMPLES

The following paragraphs describe examples of various embodiments.

Example 1 is an apparatus comprising: a stiffener for a semiconductor substrate, the stiffener with a first side and a second side opposite the first side; and a plurality of slots in the stiffener, each of the plurality of slots extending from the first side of the stiffener to the second side of the stiffener.

Example 2 may include the apparatus of example 1, or of any other example or embodiment herein, wherein the plurality of slots are proximate to an edge of the stiffener.

Example 3 may include the apparatus of example 1, or of any other example or embodiment herein, wherein the stiffener includes an opening extending from the first side of the stiffener to the second side of the stiffener.

Example 4 may include the apparatus of example 3, or of any other example or embodiment herein, wherein the plurality of slots are arranged based upon an operational frequency of circuitry that is at least partially beneath the opening of the stiffener.

Example 5 may include the apparatus of example 1, or of any other example or embodiment herein, further comprising: a gasket with a first side and a second side opposite the first side, wherein the gasket includes electromagnetic interference (EMI) blocking material, wherein the gasket includes a plurality of protrusions on the second side of the gasket, the plurality of protrusions in a configuration similar to a configuration of the plurality of slots in the stiffener; and wherein the plurality of protrusions on the second side of the gasket are inserted into the plurality of slots in the stiffener.

Example 6 may include the apparatus of example 5, or of any other example or embodiment herein, further comprising an epoxy material between at least a portion of the stiffener and the gasket.

Example 7 may include the apparatus of example 6, or of any other example or embodiment herein, wherein the epoxy material is electrically conductive.

Example 8 may include the apparatus of example 5, or of any other example or embodiment herein, further comprising a heat spreader thermally coupled with the first side of the gasket.

Example 9 may include the apparatus of example 1, or of any other example or embodiment herein, wherein a geometry of the plurality of slots in the stiffener at the first side of the stiffener includes selected one of a: circle, oval, square, regular polygon, or irregular shape.

Example 10 is a package comprising: a substrate; and a stiffener on a surface of the substrate, the stiffener with a first side and a second side opposite the first side, wherein the stiffener includes a plurality of slots, each of the plurality of slots extending from the first side of the stiffener to the second side of the stiffener.

Example 11 may include the package of example 10, or of any other example or embodiment herein, wherein the stiffener includes an opening extending from the first side of the stiffener to the second side of the stiffener.

Example 12 may include the package of example 11, or of any other example or embodiment herein, wherein the substrate further includes circuitry, the circuitry at least partially beneath the opening of the stiffener.

Example 13 may include the package of example 12, or of any other example or embodiment herein, wherein the substrate further includes high speed traces proximate to the surface of the substrate that are at least partially beneath the opening of the stiffener.

Example 14 may include the package of example 10, or of any other example or embodiment herein, further comprising a gasket with a first side and a second side opposite the first side, wherein the gasket includes electromagnetic interference (EMI) blocking material, wherein the gasket includes a plurality of protrusions on the second side of the gasket, the plurality of protrusions in a configuration similar to a configuration of the plurality of slots in the stiffener, and wherein the plurality of protrusions on the second side of the gasket are inserted into the plurality of slots in the stiffener.

Example 15 may include the package of example 14, or of any other example or embodiment herein, wherein the gasket is electrically conductive.

Example 16 may include the package of example 14, or of any other example or embodiment herein, wherein the gasket completely covers the first side of the stiffener.

Example 17 may include a package of example 14, or of any other example or embodiment herein, further comprising an epoxy between the gasket and the stiffener.

Example 18 may include a package of example 17, or of any other example or embodiment herein, wherein the epoxy is and electrically conductive epoxy, and wherein the epoxy electrically couples a ground on the surface of the substrate with the gasket.

Example 19 may include the package of example 18, or of any other example or embodiment herein, further comprising a heat spreader thermally coupled with the first side of the gasket.

Example 20 may include the package of example 19, or of any other example or embodiment herein, wherein the heat spreader includes EMI blocking material.

Example 21 may include the package of example 20, or of any other example or embodiment herein, wherein the heat spreader covers the first side of the gasket.

Example 22 may include the package of example 19, or of any other example or embodiment herein, further comprising a die coupled with the surface of the substrate, a surface of the die thermally coupled with the heat spreader.

Example 23 is a method comprising: providing a substrate, a surface of the substrate including a ground; and placing a stiffener on a surface of the substrate, the stiffener with a first side and a second side opposite the first side, wherein the stiffener includes a plurality of slots, each of the plurality of slots extending from the first side of the stiffener to the second side of the stiffener, wherein at least one of the slots is above the ground.

Example 24 may include the method of example 23, or of any other example or embodiment herein, further comprising: inserting an electrically conductive epoxy into the at least one of the slots, wherein the electrically conductive epoxy electrically couples with the ground; providing a gasket with a first side and a second side opposite the first side, wherein the gasket includes electromagnetic interference (EMI) blocking material, wherein the gasket includes a plurality of protrusions on the second side of the gasket, the plurality of protrusions in a configuration similar to a configuration of the plurality of slots in the stiffener; and electrically coupling the gasket with the ground by inserting the plurality of protrusions on the second side of the gasket into the plurality of slots in the stiffener.

Example 25 includes the method of example 24, or of any other example or embodiment herein, further comprising coupling a heat spreader to the first side of the gasket.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a stiffener for a semiconductor substrate, the stiffener with a first side and a second side opposite the first side; and
a plurality of slots in the stiffener, each of the plurality of slots extending from the first side of the stiffener to the second side of the stiffener.

2. The apparatus of claim 1, wherein the plurality of slots are proximate to an edge of the stiffener.

3. The apparatus of claim 1, wherein the stiffener includes an opening extending from the first side of the stiffener to the second side of the stiffener.

4. The apparatus of claim 3, wherein the plurality of slots are arranged based upon an operational frequency of circuitry that is at least partially beneath the opening of the stiffener.

5. The apparatus of claim 1, further comprising:
a gasket with a first side and a second side opposite the first side, wherein the gasket includes electromagnetic interference (EMI) blocking material, wherein the gasket includes a plurality of protrusions on the second side of the gasket, the plurality of protrusions in a configuration similar to a configuration of the plurality of slots in the stiffener; and
wherein the plurality of protrusions on the second side of the gasket are inserted into the plurality of slots in the stiffener.

6. The apparatus of claim 5, further comprising an epoxy material between at least a portion of the stiffener and the gasket.

7. The apparatus of claim 6, wherein the epoxy material is electrically conductive.

8. The apparatus of claim 5, further comprising a heat spreader thermally coupled with the first side of the gasket.

9. The apparatus of claim 1, wherein a geometry of the plurality of slots in the stiffener at the first side of the stiffener includes selected one of a: circle, oval, square, regular polygon, or irregular shape.

10. A package comprising:
a substrate; and
a stiffener on a surface of the substrate, the stiffener with a first side and a second side opposite the first side, wherein the stiffener includes a plurality of slots, each of the plurality of slots extending from the first side of the stiffener to the second side of the stiffener.

11. The package of claim 10, wherein the stiffener includes an opening extending from the first side of the stiffener to the second side of the stiffener.

12. The package of claim 11, wherein the substrate further includes circuitry, the circuitry at least partially beneath the opening of the stiffener.

13. The package of claim 12, wherein the substrate further includes high speed traces proximate to the surface of the substrate that are at least partially beneath the opening of the stiffener.

14. The package of claim 10, further comprising a gasket with a first side and a second side opposite the first side, wherein the gasket includes electromagnetic interference (EMI) blocking material, wherein the gasket includes a plurality of protrusions on the second side of the gasket, the plurality of protrusions in a configuration similar to a configuration of the plurality of slots in the stiffener, and wherein the plurality of protrusions on the second side of the gasket are inserted into the plurality of slots in the stiffener.

15. The package of claim 14, wherein the gasket is electrically conductive.

16. The package of claim 14, wherein the gasket completely covers the first side of the stiffener.

17. The package of claim 14, further comprising an epoxy between the gasket and the stiffener.

18. The package of claim 17, wherein the epoxy is and electrically conductive epoxy, and wherein the epoxy electrically couples a ground on the surface of the substrate with the gasket.

19. The package of claim 18, further comprising a heat spreader thermally coupled with the first side of the gasket.

20. The package of claim 19, wherein the heat spreader includes EMI blocking material.

21. The package of claim 20, wherein the heat spreader covers the first side of the gasket.

22. The package of claim 19, further comprising a die coupled with the surface of the substrate, a surface of the die thermally coupled with the heat spreader.

23. A method comprising:
providing a substrate, a surface of the substrate including a ground; and
placing a stiffener on a surface of the substrate, the stiffener with a first side and a second side opposite the first side, wherein the stiffener includes a plurality of slots, each of the plurality of slots extending from the first side of the stiffener to the second side of the stiffener, wherein at least one of the slots is above the ground.

24. The method of claim 23, further comprising:
inserting an electrically conductive epoxy into the at least one of the slots, wherein the electrically conductive epoxy electrically couples with the ground;
providing a gasket with a first side and a second side opposite the first side, wherein the gasket includes electromagnetic interference (EMI) blocking material, wherein the gasket includes a plurality of protrusions on the second side of the gasket, the plurality of protrusions in a configuration similar to a configuration of the plurality of slots in the stiffener; and
electrically coupling the gasket with the ground by inserting the plurality of protrusions on the second side of the gasket into the plurality of slots in the stiffener.

25. The method of claim 24, further comprising coupling a heat spreader to the first side of the gasket.
